(19) United States
(12) Patent Application Publication
(10) Pub. No.: US 2013/0105934 A1
(43) Pub. Date: May 2, 2013

(54) SEMICONDUCTOR DEVICE

(71) Applicant: Nobutaka MATSUOKA, Hyogo (JP)

(72) Inventor: Nobutaka MATSUOKA, Hyogo (JP)

(21) Appl. No.: 13/661,697

(22) Filed: Oct. 26, 2012

(30) Foreign Application Priority Data
Oct. 31, 2011 (JP) 2011-239790

(51) Int. Cl. H01L 29/06

(52) U.S. Cl. 257/494; 257/E29.008

(57) ABSTRACT

A semiconductor device includes a semiconductor substrate of a first electroconductive type, a first principal electrode arranged on a first side of the semiconductor substrate, a first semiconductor layer of a second electroconductive type arranged on a second side of the semiconductor substrate and at a certain distance from an edge of the semiconductor substrate, plural second semiconductor layer portions of the second electroconductive type arranged on the second side of the semiconductor substrate and positioned selectively in between the edge and the first semiconductor layer, an insulating film arranged to cover a portion of the first semiconductor layer from the edge, an electroconductive film arranged to cover portions of the insulating film and the first semiconductor layer, and a second principal electrode arranged in contact with the first semiconductor layer and the electroconductive film.

### CROSS-REFERENCE TO RELATED APPLICATION

This application is based upon and claims the benefit of priority from Japanese Patent Application No. 2011-239790, filed Oct. 31, 2011; the entire contents of which are incorporated herein by reference.

### FIELD

Embodiments described herein relate generally to a semiconductor device.

### BACKGROUND

Diodes are commonly used for power rectification with inverters and power converters, among other devices and uses. It is preferred that when a diode is switched from forward bias to reverse bias, the current concentration near the voltage-proof region, as well as surge voltage and noise, is reduced.

### DESCRIPTION OF THE DRAWINGS

FIG. 1 is a plan view illustrating the structure of a semiconductor device according to one embodiment.

FIG. 2 is a cross-sectional view taken across line A-A′ in FIG. 1.

FIG. 3 is a plan view illustrating the structure of a semiconductor device according to another embodiment.

FIG. 4 is a cross-sectional view taken across line B-B′ in FIG. 3.

FIG. 5 is a plan view illustrating the structure of a semiconductor device in a comparative example.

FIG. 6 is a cross-sectional view taken across line C-C′ in FIG. 5.

FIG. 7 is a plan view illustrating the structure of a semiconductor device according to another embodiment.

FIG. 8 is a cross-sectional view taken across line D-D′ in FIG. 7.

FIG. 9 is a plan view illustrating the structure of a semiconductor device according to another embodiment.

FIG. 10 is a cross-sectional view taken across line E-E′ in FIG. 9.

FIG. 11 is a plan view illustrating the structure of a semiconductor device according to another embodiment.

FIG. 12 is a cross-sectional view taken across line F-F′ in FIG. 11.

### DETAILED DESCRIPTION

In general, according to one embodiment, a semiconductor device includes a semiconductor substrate of a first conductivity type, a first principal electrode arranged on one side (first side) of the semiconductor substrate, a first semiconductor layer of a second conductivity type arranged on the other side (second side) of the semiconductor substrate and at a certain distance from an edge of the semiconductor substrate, plural second semiconductor layer portions of the second conductivity type arranged on the other side of the semiconductor substrate and selectively positioned between the edge and the first semiconductor layer, an insulating film arranged to cover a portion of the first semiconductor layer to the edge, an electroconductive film arranged to cover portions of the insulating film and the first semiconductor layer, and a second principal electrode arranged in contact with the first semiconductor layer and the electroconductive film.

Examples of the invention will be explained with reference to figures. In the present embodiment, it is assumed that the first conductivity type is the N type, while the second conductivity type is the P type. However, the embodiment may also be used when the first conductivity type is the P type, and the second conductivity type is the N type. In the following explanation, keys of N+, N, P+ and P indicate the relative high/low levels of the impurity (e.g., dopant) concentration of each conductivity type. That is, N+ indicates that the N type impurity concentration is higher than that of N. Similarly, P+ indicates that the P type impurity concentration is higher than that of P.

According to the embodiments, there is provided a semiconductor device that suppresses current concentration at locations of the device near the voltage-proof region with minimal power loss.

### Embodiment 1

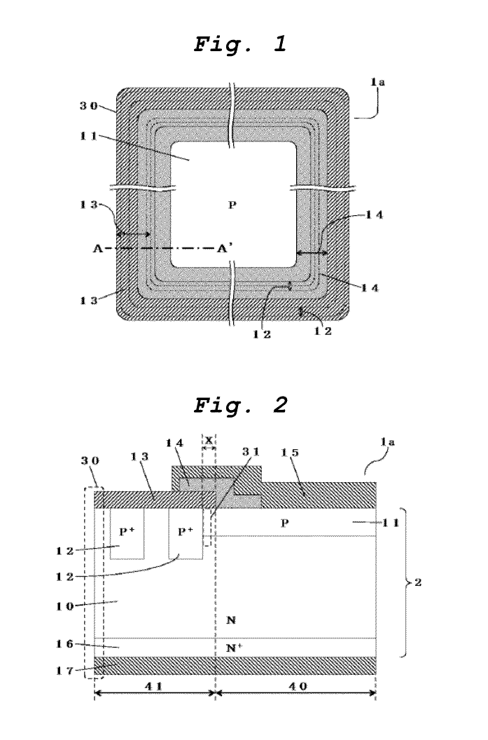

FIG. 1 is a plan view illustrating the structure of a semiconductor device 1a related to Embodiment 1. FIG. 2 is a cross-sectional view taken across line A-A′ of FIG. 1. In FIG. 1, an anode electrode structure 15 shown in FIG. 2 is not shown in the plan view of FIG. 1.

As shown in FIG. 1 and FIG. 2, the semiconductor device la related to Embodiment 1 has a diode structure. The diode structure has an N type drift layer 10 arranged on a semiconductor substrate 2. On one side (e.g., first side) of the semiconductor substrate 2, an N+ type cathode layer 16 is arranged. In addition, on the first side of the semiconductor substrate 2, a cathode electrode 17 (e.g., the first principal electrode) is arranged.

On the other side (e.g., second side) of the semiconductor substrate 2, a P type anode layer 11 (e.g., the first semiconductor layer) is selectively spaced from an edge 30 of the semiconductor device 1a. On the second side of the semiconductor substrate 2, between the edge 30 of the semiconductor device 1a and the anode layer 11, a P+ type guard ring layer 12 (e.g., the second semiconductor layer) is selectively arranged. As shown in FIG. 1, a plan view, the P+ type guard ring layer 12 is arranged as a loop around the outer peripheral portion of the semiconductor device 1a near the edge 30 of the semiconductor device 1a.

The region containing the P+ type guard ring layer 12 comprises a peripheral voltage-proof region. The peripheral voltage-proof region refers to an region that may suppress the application of a high electric field near an end 31 of the P type anode layer 11 when a reverse voltage is applied on the semiconductor device 1a. The voltage-proof structure is not limited to the guard ring structure shown. For example, a re-surf structure, etc. may also be used. In the example shown in FIG. 1 and FIG. 2, two P+ type guard ring layer portions 12 are formed. However, this is merely an example. The number of the P+ type guard ring layers 12 maybe determined according to the desired voltage-proof performance of the semiconductor device 1a, and there is no specific restriction on it.

On the second side of the semiconductor substrate 2, an insulating film 13 is formed from the edge 30 to a portion of the P type anode layer 11. A barrier metal layer 14 (e.g., electroconductive film) is then arranged to cover portions of the insulating film 13 and the P type anode layer 11. In the example shown in FIG. 1 and FIG. 2, a barrier metal layer 14 on the insulating film 13 is formed at a certain distance from the edge 30. However, the barrier metal layer 14 may also be formed at or to the edge 30.

An anode electrode structure 15 (e.g., the second principal electrode) is arranged to cover the barrier metal layer 14 and the P type anode layer 11. Here, the anode electrode structure 15 and cathode electrode 17 may be made of aluminum (Al) or the like. However, other electroconductive materials may also be used. Similarly, the barrier metal layer 14 may also be made of any of various types of electroconductive materials. The material for making the barrier metal layer 14 has a resistivity higher than that of the material for making the anode electrode structure 15. As far as the form of the anode electrode structure 15 is concerned, in addition to the forms shown in FIG. 1 and FIG. 2, various other forms may be used, such as the form wherein the anode electrode structure 15 of the semiconductor device 1a of Embodiment 1 is formed up to the edge 30. A practical example will be explained later.

The operation and characteristic features of the semiconductor device 1a in Embodiment 1 will be explained. For the semiconductor device 1a, when a forward voltage is applied on it, holes move from the anode electrode structure 15 and barrier metal layer 14 through the P type anode layer 11 and flow into the N type drift layer 10. While the holes flow from the anode electrode structure 15 and barrier metal layer 14 into the N type drift layer 10, electrons flow from the cathode electrode 17 through the N+ type cathode layer 16 into the N type drift layer 10. As a result, a conductivity modulation phenomenon takes place, and the resistance of the N type drift layer 10 decreases. The holes flowing into the N type drift layer 10 flow to the cathode electrode 17 and, similarly, the electrons flowing into the N type drift layer 10 flow to the barrier metal layer 14 and anode electrode structure 15. That is, when forward voltage is applied, the semiconductor device la is turned on.

In this case, as an inner region 40 of the semiconductor device 1a is a region where the P type anode layer 11 and the barrier metal layer 14, as well as the anode electrode structure 15, are in direct contact with each other, many holes flow into the N type drift layer 10 in the inner region 40. On the other hand, an outer region 41 of the semiconductor device 1a is a region where the P type anode layer 11 and the barrier metal layer 14, as well as anode electrode structure 15, are not in contact with each other. While there are holes flowing into the outer region 41, the holes are in a relatively smaller quantity than as compared to the quantity of holes of the N type drift layer 10 in the inner region 40. Consequently, when the semiconductor device 1a is on, there are many more holes in the N type drift layer 10 in the inner region 40 than there are holes in the N type drift layer 10 in the outer region 41.

When the semiconductor device 1a is turned off (e.g., a reverse voltage is applied on the semiconductor device 1a), the electrons in the N type drift layer 10 move through the N+ type cathode layer 16 to the cathode electrode 17. In addition, the holes in the N type drift layer 10 move through the P type anode layer 11 to the barrier metal layer 14 and anode electrode structure 15.

In the following, the movement of the holes in the N type drift layer 10 when the semiconductor device 1a is turned off will be explained in more detail. The holes in the N type drift layer 10 in the inner region 40 flow to the P type anode layer 11, and the holes then move from the P type anode layer 11 to the barrier metal layer 14 and the anode electrode structure 15. In this manner, high current concentration is suppressed when the holes flow to the P type anode layer 11 from the lower side.

The holes in the N type drift layer 10 in the outer region 41 also flow to the P type anode layer 11, then move from the P type anode layer 11 to the barrier metal layer 14 and anode electrode structure 15. The flow of holes is concentrated in the end 31 of the P type anode layer 11. However, as the barrier metal layer 14 is arranged above the end 31 of the P type anode layer 11, there is a resistance applied by the barrier metal layer 14, and, due to the ballast resistance effect that suppresses the current to a certain level, it is possible to decrease the current concentration.

In this manner, it is possible to suppress current concentration when the semiconductor device is turned off. Consequently, it is possible to prevent the various problems that would occur due to current concentration. Additionally, it is possible to prolong the service life of the semiconductor device 1a. Also, it is possible to vary the conditions upon use of the semiconductor device 1a (e.g., voltage rating, current rating, temperature range for application, etc.).

The barrier metal layer 14 arranged in the semiconductor device 1a of Embodiment 1 is made of a material with a resistivity higher than that of the anode electrode structure 15. It may be made of an electroconductive material. Consequently, even in the contact area between the barrier metal layer 14 and the P type anode layer 11, electrical connection between the P type anode layer 11 and the anode electrode structure 15 may still be maintained. Consequently, the power loss caused by setting the barrier metal layer 14 may be decreased, and it is possible to realize the effect in minimizing the current concentration at the end 31 as explained above.

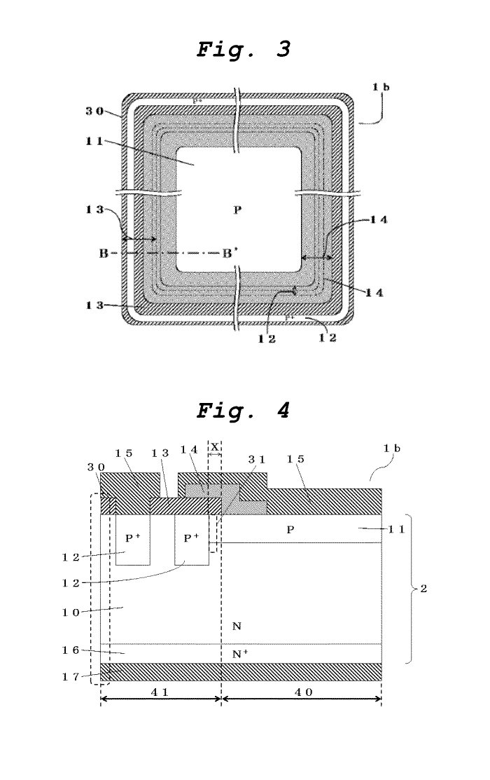

In the following, as a modified example of the anode electrode structure 15, a modified example shown in FIG. 3 and FIG. 4 is provided. FIG. 3 is a plan view illustrating the structure of a semiconductor device 1b related to the modified example of Embodiment 1. FIG. 4 is a cross-sectional view taken across line B-B′ in FIG. 3. In FIG. 3, the anode electrode structure 15 is not shown in the plan view. The same keys as those in the above for the semiconductor device 1a in Embodiment 1 shown in FIG. 1 and FIG. 2 are used to represent the various parts in this modified example.

The semiconductor device 1b in the modified example differs from the semiconductor device 1a in Embodiment 1 in that the insulating film 13 arranged on the upper surface of the P+ type guard ring layer 12 is thinned, so that at least one of the P+ type guard ring layers 12 and the anode electrode structure 15 contact each other.

In the semiconductor device 1b of the modified example of Embodiment 1, the barrier metal layer 14 with a resistivity higher than that of the electroconductive material used for the anode electrode structure 15 is arranged on the end 31. Consequently, for the semiconductor device 1b in the modified example of Embodiment 1, also, it is possible to suppress the concentration of electric field at the end 31 when the semiconductor device 1b is turned off, without a power loss.

As shown in FIG. 3 and FIG. 4, the entire surface of the upper side of the outermost P+ type guard ring layer 12 is in contact with the anode electrode structure 15. However, the semiconductor device 1b may be modified in which contact is made with only a portion of the surface on the upper side of the outermost P+ type guard ring layer 12. Also, it is possible to adopt a modification to provide contact between plural P+type guard ring layers 12 and the anode electrode structure 15.

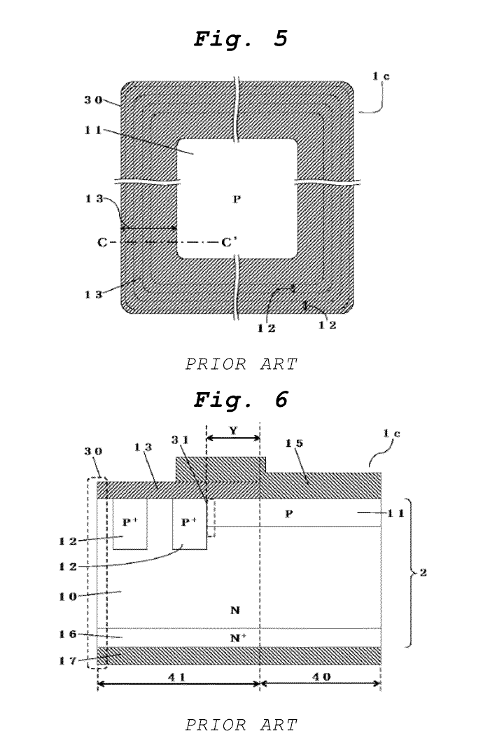

In the following, the structure of a semiconductor device 1c of the related art will be explained as a comparative example. FIG. 5 is a plan view illustrating the structure of the semiconductor device 1c in the comparative example. FIG. 6 is a cross-sectional view taken across line C-C′ of FIG. 5. In FIG. 5, the anode electrode structure 15 is not shown in the plan view. The same keys as those in the above for the semiconductor device 1a in Embodiment 1 shown in FIG. 1 and FIG. 2 are used to indicate the various parts of the comparative example.

The semiconductor device 1c differs in the comparative example from Embodiment 1 in that the barrier metal layer 14 is not arranged, and the insulating film 13 is arranged wider than that in Embodiment 1. That is, as shown in FIG. 2 and FIG. 4, a length Y as shown in FIG. 6 is longer than a length X shown in FIG. 2.

In the following, the problems of the semiconductor device 1c having the diode structure will be explained. For the semiconductor device 1c having a diode structure in which a peripheral voltage-proof region is formed as P+ type guard ring layer 12, because the length of the insulating film 13 in FIG. 2 is shorter than the length Y shown in FIG. 6, current is concentrated near the end 31 of the P type anode layer 11 when the semiconductor device 1c is turned off.

In the following, the problem will be explained in more detail. First of all, when a forward voltage is applied on the semiconductor device 1c (i.e., when the semiconductor device 1c is turned on), holes are present in the N+ type cathode layer 16. As the semiconductor device 1c is turned off, the holes in the N+ type cathode layer 16 move through the P type anode layer 11 to the anode electrode structure 15. In this case, the holes present in the N+ type cathode layer 16 near the edge 30 of the semiconductor substrate 2 move through near the end 31 of the P type anode layer 11 to the anode electrode structure 15. That is, current is concentrated near the end 31 of the P type anode layer 11. Such a current concentration leads to an increase in problems with the semiconductor device 1c, restrictions on the conditions for use of the semiconductor device 1c, and other operational problems.

For the semiconductor device 1c in the comparative example, in order to solve the problem, the insulating film 13 is formed longer as length Y shown in FIG. 6 so as to suppress the concentration of electric field to the end 31.

However, for the semiconductor device 1c of the comparative example, the volume of the inner region 40 is reduced and the volume of the outer region 41 is increased. That is, the area of the P type anode layer 11 in contact with the anode electrode structure 15 is decreased. As a consequence, the effective area for operation of the semiconductor device 1c is also decreased. Consequently, for the semiconductor device 1c in the comparative example, although it is possible to alleviate the concentration of electric field at the end 31, a new problem involving power loss is produced.

On the other hand, in the case of Embodiment 1, instead of decreasing the area of the P type anode layer 11 in contact with the anode electrode structure 15 and forming longer insulating film 13, a barrier metal layer 14 is provided. Consequently, although the end 31 has a resistance component, because it is not an insulator, current is not completely absent. Therefore, the power loss is greatly reduced in the semiconductor device 1a of Embodiment 1 as compared to the level of power loss in the comparative example.

As explained above, for the semiconductor device 1a in Embodiment 1, by arranging a barrier metal layer 14 with a resistivity that is higher than that of the electroconductive material used in making the anode electrode structure 15, on the end 31, it is possible to suppress the power loss and reduce the concentration of electric field at the end 31 that would otherwise take place when the semiconductor device is turned off.

### Embodiment 2

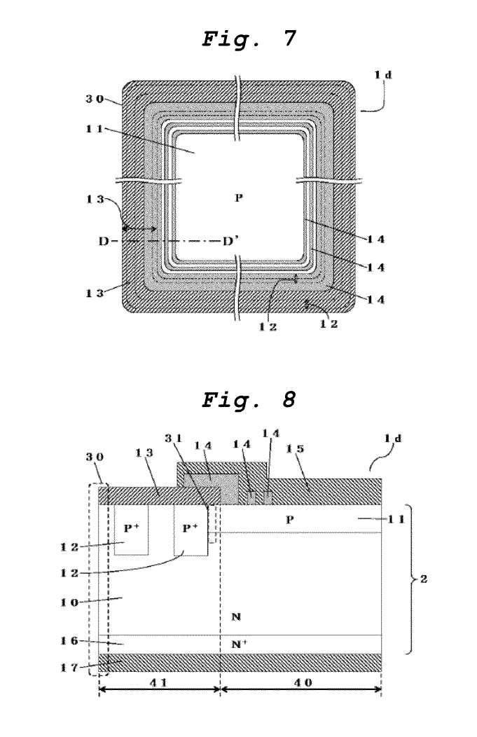

FIG. 7 is a plan view illustrating the structure of a semiconductor device 1d related to Embodiment 2. FIG. 8 is a cross-sectional view taken across line D-D′ in FIG. 7. In FIG. 7, the anode electrode structure 15 is not shown in the plan view. The same keys as those in the above for the semiconductor device 1a in Embodiment 2 shown in FIG. 1 and FIG. 2 are used in FIGS. 7 and 8.

The semiconductor device 1d in Embodiment 2 differs from the semiconductor device 1a in Embodiment 1 in that the barrier metal layer 14 arranged on the end 31 is selectively divided into plural portions as shown in FIG. 7 and FIG. 8. Here, division of the barrier metal layer 14 is provided in the circumferential direction in the plan view of FIG. 7. As shown in FIG. 7 and FIG. 8, the barrier metal layer 14 is divided equidistantly at two locations. However, this is merely an example, and there is no specific restriction on the number of the divisions and locations for the barrier metal layers 14. Also, it is not necessary to have a constant spacing between divisions of the barrier metal layers 14 when Embodiment 2 is used.

For the semiconductor device 1d in Embodiment 2, also, a barrier metal layer 14 having a higher resistivity than that of the electroconductive material for making the anode electrode structure 15 is formed on the end 31. Consequently, for the semiconductor device 1d in Embodiment 2, it is possible to suppress the power loss and the concentration of electric field at the end 31 when the semiconductor device 1d is turned off.

### Embodiment 3

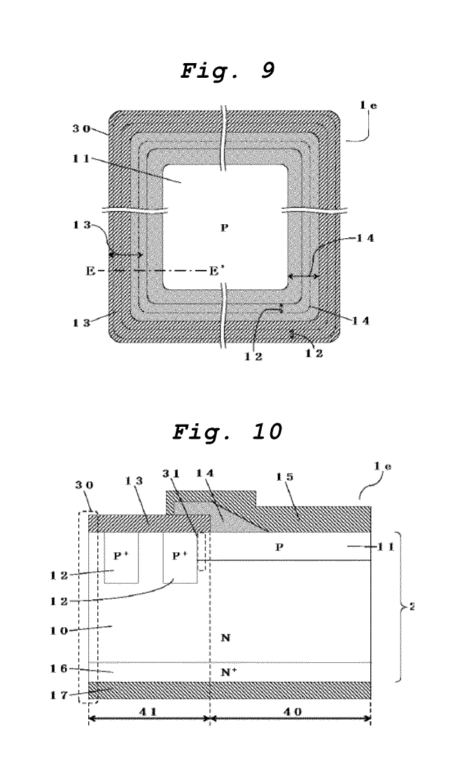

FIG. 9 is a plan view illustrating the structure of a semiconductor device 1e related to Embodiment 3. FIG. 10 is a cross-sectional view taken across line E-E′ of FIG. 9. In FIG. 9, the anode electrode structure 15 is not shown in the plan view. The same keys as those in the above for the semiconductor device 1a in Embodiment 1 shown in FIG. 1 and FIG. 2 are used here for the various parts of this embodiment.

The semiconductor device 1e in Embodiment 3 differs from the semiconductor device 1a in Embodiment 1 in that the thickness of the barrier metal layer 14 arranged on the end 31 decreases inwardly as the position becomes farther from the insulating film 13 as shown in FIG. 10. As shown in FIG. 10, the thickness of the barrier metal layer 14 is variable and becomes thinner over the distance in a linear slope. However, this is merely an example, and Embodiment 3 may also be provided by having the thickness become lesser over the distance with a regressive curved pattern or other non-linear shape having a thickness that decreases along the distance. That is, there is no specific restriction on how to make the thickness of the barrier metal layer 14 become thinner over the distance.

For the semiconductor device 1e in Embodiment 3, a barrier metal layer 14 with a resistivity higher than that of the electroconductive material used for the anode electrode structure 15 is also formed on the end 31. Consequently, for the semiconductor device 1e in Embodiment 3, it is also possible to suppress power loss and the concentration of the electric field at the end 31 when the semiconductor device 1e is turned off.

According to Embodiment 3, the thickness of the barrier metal layer 14 decreases inwardly of the semiconductor device (e.g., in a direction away from the insulating film 13). Consequently, the resistance component attributed by the barrier metal layer 14 decreases as the position moves from the insulating film 13. As a result, in the region of the end 31, also, the portion prone to concentration of electric field has a relatively high resistance component. As the resistance component is gradually decreased as the position moves from the end 31, it is possible to smoothly suppress concentration of the electric field.

### Embodiment 4

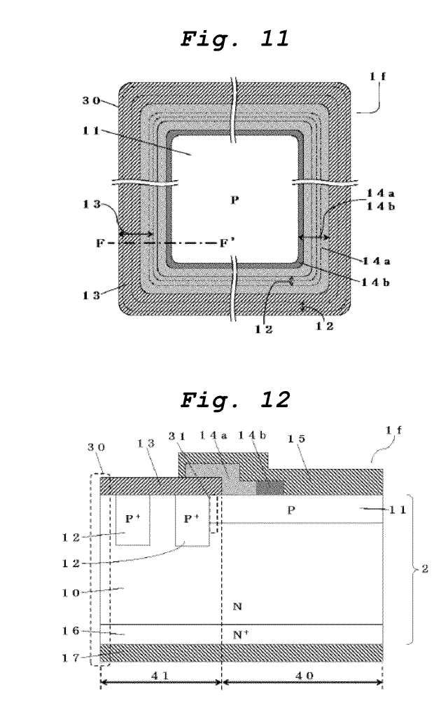

FIG. 11 is a plan view illustrating the structure of a semiconductor device 1f related to Embodiment 4. FIG. 12 is a cross-sectional view taken across line F-F′ of FIG. 11. In FIG. 11, the anode electrode structure 15 is not shown in the plan view. The same keys as those in the above for the semiconductor device 1a in Embodiment 1 shown in FIG. 1 and FIG. 2 are used for the various parts of this embodiment.

The semiconductor device 1f in Embodiment 4 differs from the semiconductor device 1a in Embodiment 1 in that the barrier metal layer 14 formed on the end 31 as shown in FIG. 1 and FIG. 2 is replaced by barrier metal layers 14a, 14b made of two types of electroconductive materials, respectively, as shown in FIG. 11 and FIG. 12. According to this embodiment, the barrier metal layer 14b of the portion at a certain distance from the insulating film 13 is formed so that the resistance of the barrier metal layer 14b is lower than the resistance of the barrier metal layer 14a. That is, as the magnitudes of the resistance are compared with each other, the resistance of the barrier metal layer 14b is greater than the resistance of the anode electrode structure 15, and the resistance of the barrier metal layer 14b is lower than that of the barrier metal 14a. The reason for using this constitution will be explained later.

Two types of electroconductive materials are used to form the barrier metal layers 14a, 14b as shown in FIG. 11 and FIG. 12. However, there is no specific restriction on the number of materials for forming them, as long as the resistance becomes lesser at the position located farthest from the insulating film 13.

For the semiconductor device 1f in Embodiment 4, the barrier metal layers 14a, 14b having a resistivity higher than that of the electroconductive material used for the anode electrode structure 15 are arranged on the end 31. Consequently, for the semiconductor device 1f in Embodiment 4, it is also possible to suppress power loss and concentration of electric field to the end 31 when the semiconductor device 1f is turned off.

According to Embodiment 4, as the magnitude of resistance of the barrier metal layers 14a, 14b becomes lesser as the position becomes farther from the insulating film 13, the resistance component attributed by the barrier metal layers 14a, 14b decreases as the position becomes farther from the insulating film 13. This feature has the following advantage: because the portion in the region of the end 31 is prone to concentration of electric field, and has a relatively higher resistance component, and the resistance component gradually becomes lower as the position becomes farther from the end 31, it is possible to smoothly suppress the concentration of electric field.

According to the present embodiment with this constitution, a semiconductor substrate, such as silicon (Si), may be used for the semiconductor substrate 2. However, it is not limited to it. One may also adopt silicon carbide (SiC), gallium nitride (GaN), and other compound semiconductors, as well as diamond and other wide-gap semiconductors.

In the above, the semiconductor devices 1a, 1b, 1c, 1d, 1e, 1f of the present embodiment maybe manufactured using the ion implanting method. However, the manufacturing method is not limited to the ion implanting method. One may also adopt the epitaxial method or a combination of both methods to form the semiconductor device. When the epitaxial method is used to manufacture the semiconductor device, for example, an N+ type cathode layer 16 or the like is used as the semiconductor substrate 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate having a first conductivity type;
a first principal electrode arranged on a first side of the semiconductor substrate;
a first semiconductor layer of a second conductivity type arranged on a second side of the semiconductor substrate and spaced from an edge of the semiconductor substrate;
a plurality of second semiconductor layers of the second conductivity type provided in the semiconductor substrate on the second side thereof and selectively laterally positioned between the edge and the first semiconductor layer;
an insulating film overlying a portion of the first semiconductor layer from the edge;
an electroconductive film arranged to cover portions of the insulating film and the first semiconductor layer; and
a second principal electrode provided on the second side of the semiconductor substrate in contact with the first semiconductor layer and the electroconductive film and overlying a portion of the insulating film.

2. The semiconductor device according to claim 1, wherein a thickness of the electroconductive film on the first semiconductor layer decreases as the electroconductive film extends in a direction away from the insulating film.

3. The semiconductor device according to claim 1, wherein the electroconductive film on the first semiconductor layer comprises a metal, and a resistance value of the electroconductive film decreases as the electroconductive film extends in a direction away from the insulating film.

4. The semiconductor device according to claim 1, wherein the insulating film on an upper side of the second semiconductor layer is selectively divided by one of the plurality of the second semiconductor layers, and another of the plurality of the second semiconductor layers is in contact with the second principal electrode.

5. The semiconductor device according to claim 1, wherein a resistance of the electroconductive film is greater than a resistance of the second principal electrode.

6. The semiconductor device according to claim 5, wherein the electroconductive film on the first semiconductor layer is selectively divided to provide a spacing therebetween.

7. The semiconductor device according to claim 5, wherein a thickness of the electroconductive film on the first semiconductor layer decreases as the electroconductive film extends in a direction away from the insulating film.

8. The semiconductor device according to claim 5, wherein the electroconductive film on the first semiconductor layer comprises a metal, and a resistance value of the electroconductive film decreases as the electroconductive film extends in a direction away from the insulating film.

9. The semiconductor device according to claim 5, wherein the insulating film on an upper side of the second semiconductor layer is selectively divided by one of the plurality of the second semiconductor layers, and another of the plurality of the second semiconductor layers is in contact with the second principal electrode.

10. The semiconductor device according to claim 1, wherein the electroconductive film on the first semiconductor layer is selectively divided to provide a spacing therebetween.

11. The semiconductor device according to claim 10, wherein a thickness of the electroconductive film on the first semiconductor layer decreases as the electroconductive film extends in a direction away from the insulating film.

12. The semiconductor device according to claim 10, wherein the electroconductive film on the first semiconductor layer comprises a metal, and a resistance value of the electroconductive film decreases as the electroconductive film extends in a direction away from the insulating film.

13. The semiconductor device according to claim 10, wherein the insulating film on an upper side of the second semiconductor layer is selectively divided by one of the plurality of the second semiconductor layers, and another of the plurality of the second semiconductor layers is in contact with the second principal electrode.

14. A semiconductor device comprising:
a semiconductor substrate having a first conductivity type;
a first electrode arranged on a first side of the semiconductor substrate;
a first semiconductor layer of a second conductivity type provided on a second side of the semiconductor substrate and spaced from an edge of the semiconductor substrate;
a plurality of second semiconductor layers of the second conductivity type provided in the semiconductor substrate on the second side thereof and selectively laterally positioned between the edge and the first semiconductor layer;
an insulating film overlying a portion of the first semiconductor layer from the edge to a position inward from the edge;
a second electrode provided on the second side of the semiconductor substrate overlying a portion of the insulating film; and
an electroconductive film disposed between the insulating film and the second electrode, at least a portion of the electroconductive film in contact with the first semiconductor layer and the second electrode.

15. The semiconductor device according to claim 14, wherein a thickness of the electroconductive film decreases as the electroconductive film extends in a direction away from the edge.

16. The semiconductor device according to claim 14, wherein the electroconductive film comprises a metal, and a resistance value of the electroconductive film decreases as the electroconductive film extends in a direction away from the edge.

17. The semiconductor device according to claim 14, wherein the insulating film on an upper side of the second semiconductor substrate is selectively divided by one of the plurality of the second semiconductor layers, and another of the plurality of the second semiconductor layers is in contact with the second electrode.

18. The semiconductor device according to claim 14, wherein the electroconductive film on the first semiconductor layer is selectively divided to provide a spacing therebetween.

19. The semiconductor device according to claim 14, wherein a resistance of the electroconductive film is greater than a resistance of the second electrode.

20. The semiconductor device according to claim 19, wherein the electroconductive film comprises a metal, and a resistance value of the electroconductive film decreases as the electroconductive film extends in a direction away from the edge.
